(19) United States
(12) Patent Application Publication
(10) Pub. No.: US 2005/0017351 A1
(43) Pub. Date: Jan. 27, 2005

(54) Silicon on diamond wafers and devices

(76) Inventor: Kramadhati V. Ravi, Atherton, CA (US)

Correspondence Address: Schwegman, Lundberg, Woessner & Kluth, P.A., P.O. Box 2938, Minneapolis, MN, 55402, US

(21) Appl. No.: 10/610,356

(22) Filed: Jun. 30, 2003

(51) Int. Cl. H01L 23/34

(52) U.S. Cl. 257/720

(57) ABSTRACT

A heat dissipation device includes a first silicon layer, a second silicon layer, and a diamond layer sandwiched between the first silicon layer and the second silicon layer. A method for forming an electronic device includes sandwiching a layer of diamond between a first layer of silicon and a second layer of silicon, and forming an electrical device on one of the first layer of silicon or the second layer of silicon. The method further includes forming an epitaxial layer on one of the first layer of silicon and the second layer of silicon. An electrical device is formed in the epitaxial layer.

### FIELD OF THE INVENTION

The present invention is related to a heat dissipation system for a wafer which is cut into individual dies. More specifically, the present invention relates to a silicon on diamond wafers and devices and the manufacture of the same.

### BACKGROUND OF THE INVENTION

The semiconductor industry has seen tremendous advances in technology in recent years that have permitted dramatic increases in circuit density and complexity, and equally dramatic decreases in power consumption and package sizes. Present semiconductor technology now permits single-chip microprocessors with many millions of transistors, operating at speeds of tens (or even hundreds) of MIPS (millions of instructions per second), to be packaged in relatively small, air-cooled semiconductor device packages. As integrated circuit devices, microprocessors and other related components are designed with increased capabilities and increased speed, additional heat is generated from these components. As packaged units and integrated circuit die sizes shrink, the amount of heat energy given off by a component for a given unit of surface area is also on the rise. The majority of the heat generated by a component, such as a microprocessor, must be removed from the component to keep the component at an operating temperature, and to prevent failure of the component. If the heat generated is not removed from the component, the heat produced can drive the temperature of the component to levels that result in failure of the component. In some instances, the full capability of certain components can not be realized since the heat the component generates at the full capability would result in failure of the component.

A seemingly constant industry trend for all electronic devices, and especially for personal computing, is to constantly improve products by adding increased capabilities and additional features. For example, the electronics industry has seen almost a 50 fold increase in processing speed over the last decade. Increasing in the speed of a microprocessor increases the amount of heat output from the microprocessor. Furthermore, as computer related equipment becomes smaller and more powerful, more components are being used as part of one piece of equipment. As a result, the amount of heat generated on a per unit volume basis is also on the increase. A portion of an amount of heat produced by semiconductors and integrated circuits within a device must be dissipated to prevent operating temperatures that can potentially damage the components of the equipment, or reduce the lifetime of the individual components and the equipment.

Currently, circuitry for a plurality of integrated circuits is formed on a wafer of solid silicon. Leads, such as pins or balls, are also formed to provide inputs and outputs to the circuitry on the wafer and to the individual die. After the circuitry is formed, the wafer is diced or cut into individual dies each having the circuitry for an individual integrated circuit. Each die which includes an integrated circuit has a front side and a back side. The front side of the die includes leads for inputs, outputs and power to the integrated circuit. The die and integrated circuitry generate heat. Currently, a heat sink is attached to the back side of the integrated circuit to remove heat from the die and integrated circuit therein. There is generally a limitation on the amount of heat that can be extracted from the back side of the integrated circuit or die, because of the thermal resistance induced by the thermal interface materials (such as a silicon die, a heat pipe to transport heat from the die to the heat sink, and any thermal grease or adhesives) used between the back side of the integrated circuit die and the heat sink. Most heat sinks are formed from copper or aluminum. The materials used currently as heat sinks have a limited ability to conduct heat. Relatively large fin structures are also provided to increase the amount of heat removed via conduction. Fans are also provided to move air over the fin structures to aid in the conduction of heat. The use of aluminum and copper heat sinks with fin structures are now approaching their practical limits for removal of heat from a high performance integrated circuit, such as the integrated circuits that include dies for microprocessors. When heat is not effectively dissipated, the dies develop “hot spots” or areas of localized overheating. Ultimately, the circuitry within the die fails. When the die fails, the electrical component also fails.

In some instances, aluminum and copper heat sinks are replaced with a diamond heat sink. Diamond heat sinks are difficult to manufacture and expensive. One aspect of a diamond heat sink is that one major surface of the heat sink must be ground smooth to provide a good thermal connection at a thermal interface. Grinding or smoothing diamond is time consuming.

### BRIEF DESCRIPTION OF THE DRAWINGS

The invention is pointed out with particularity in the appended claims. However, a more complete understanding of the present invention may be derived by referring to the detailed description when considered in connection with the figures, wherein like reference numbers refer to similar items throughout the figures, and:

FIG. 1 is a top view of a printed circuit board having a component with a die having a buried diamond layer, according to an embodiment of this invention.

FIG. 2 is a side view of a heat dissipation device including a diamond layer sandwiched between a first silicon layer and a second silicon layer, according to an embodiment of this invention.

FIG. 3 is a side view of a heat dissipation device that includes a diamond layer sandwiched between a first silicon layer and a second silicon layer, according to an embodiment of this invention.

FIG. 4 is a schematic view of a wafer that includes a buried diamond layer sandwiched between a first silicon layer and a second silicon layer, according to an embodiment of this invention.

FIG. 5A illustrates a wafer or heat dissipation device after a layer of diamond has been placed on the wafer during the process of forming the buried diamond layer, according to an embodiment of this invention.

FIG. 5B illustrates a wafer or heat dissipation device after a layer of polysilicon has been placed over the layer of diamond during the process of forming the buried diamond layer, according to an embodiment of this invention.

FIG. 5C illustrates a wafer or heat dissipation device after another layer of silicon is attached to the polysilicon layer of the wafer during the process of forming the buried diamond layer, according to an embodiment of this invention.

FIG. 5D illustrates a wafer or heat dissipation device after the device quality silicon layer has been thinned and polished during the process of forming the buried diamond layer, according to an embodiment of this invention.

FIG. 5E illustrates a wafer or heat dissipation device after an epitaxial layer has been placed on the device quality layer during the process of forming the buried diamond layer, according to an embodiment of this invention.

FIG. 6 is a flow diagram showing a method for forming a buried diamond layer on a wafer, according to the embodiment of this invention shown in FIGS. 5A-5E.

FIG. 7A illustrates the wafer or heat dissipation device before a layer of polysilicon is placed over the layer of diamond during the process of forming the buried diamond layer, according to an embodiment of this invention.

FIG. 7B illustrates the wafer or heat dissipation device after a layer of polysilicon is placed over the layer of diamond during the process of forming the buried diamond layer, according to an embodiment of this invention.

FIG. 8 illustrates a wafer or heat dissipation device after a buried oxide layer has been placed on the device quality silicon layer and after an epitaxial layer has been bonded to the buried oxide layer during the process of forming the buried diamond layer, according to an embodiment of this invention.

FIG. 9 is a flow diagram showing a method for forming a buried diamond layer on a wafer, according to another embodiment of this invention.

FIG. 10 is a flow diagram of a method for forming a buried diamond layer on a wafer, according to yet another embodiment of this invention.

FIG. 11 is a flow diagram of a method for forming a buried diamond layer on a wafer, according to still another embodiment of this invention.

FIG. 12 is a flow diagram of a method for forming an electronic device, according to an embodiment of this invention.

The description set out herein illustrates the various embodiments of the invention, and such description is not intended to be construed as limiting in any manner.

### DETAILED DESCRIPTION

In the following detailed description of the preferred embodiments, reference is made to the accompanying drawings that form a part hereof, and in which are shown by way of illustration specific embodiments in which the invention can be practiced. The embodiments illustrated are described in sufficient detail to enable those skilled in the art to practice the teachings disclosed herein. Other embodiments can be utilized and derived therefrom, such that structural and logical substitutions and changes can be made without departing from the scope of present inventions. The following detailed description, therefore, is not to be taken in a limiting sense, and the scope of various embodiments of the invention is defined only by the appended claims, along with the full range of equivalents to which such claims are entitled.

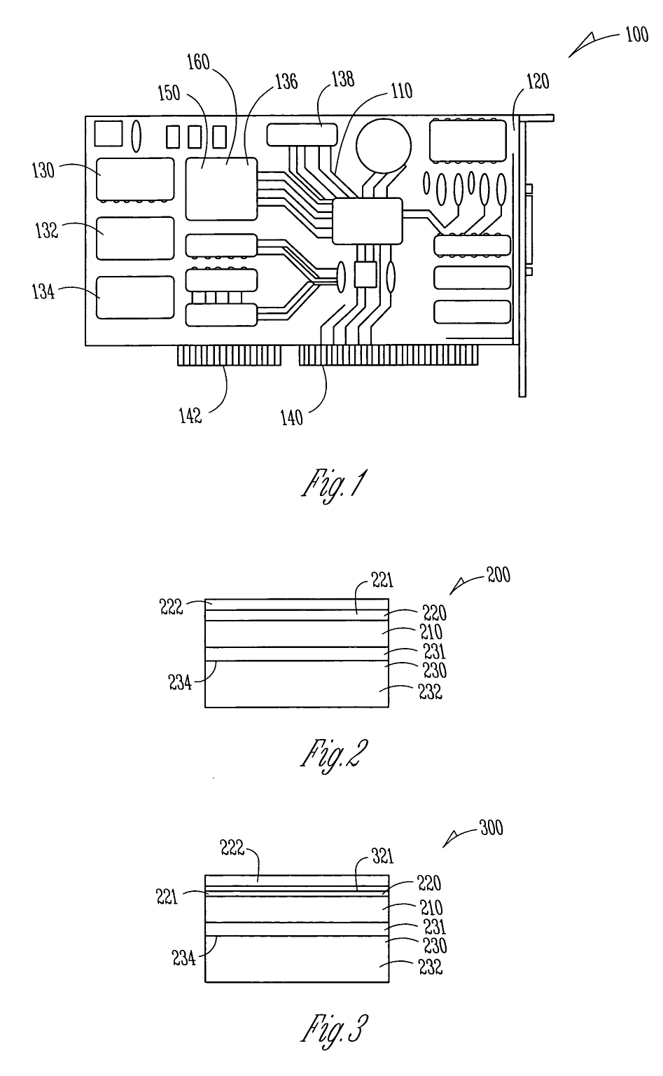

FIG. 1 is a top view of a printed circuit board 100, having a component with a die having a buried diamond layer, according to an embodiment of the invention. The printed circuit board (“PCB”) 100 is a multi-layer plastic board that includes patterns of printed circuits on one or more layers of insulated material. The patterns of conductors correspond to wiring of an electronic circuit formed on one or more of the layers of the printed circuit board 100. The printed circuit board 100 also includes electrical traces 110. The electrical traces 110 can be found on an exterior surface 120 of a printed circuit board 100 and also can be found on the various layers within the printed circuit board 100. Printed circuit boards also include through holes (not shown in FIG. 1) which are used to interconnect traces on various layers of the printed circuit board 100. The printed circuit board can also include planes of metallized materials such as ground planes, power planes, or voltage reference planes (not shown in FIG. 1).

The printed circuit board 100 is also populated with various components 130, 132, 134, 136, 138. The components 130, 132, 134, 136, 138 can either be discreet components or semiconductor chips which include thousands of transistors. The components 130, 132, 134, 136, 138 can use any number of technologies to connect to the exterior surface 120 of the circuit board or to the printed circuit board 100. For example, pins may be inserted into plated through holes or pins may be extended through the printed circuit board 100. An alternative technology is surface mount technology where an electrical component, such as component 136, mounts to an array of pads on the exterior surface 120 of the printed circuit board 100. For example, component 136 could be a ball grid array package or device that has an array of balls or bumps that interact or are connected to a corresponding array of pads on the exterior surface 120 of the printed circuit board 100. The printed circuit board 100 can also include connectors for making external connections to other electrical or electronic devices.

The component 136 is a central processing chip or microprocessor. The component 136 includes a die 160 having a diamond layer sandwiched between a first silicon layer and a second silicon layer. The die 160 with the diamond layer sandwiched between a first silicon layer and a second silicon layer will be further detailed in the following paragraphs. The component 136 may also have a heat sink 150 such as an integrated heat spreader. The heat sink 150 is attached to the back side of the component 136. The heat sink 150 removes heat from the back side of the die 160 associated with the component 136. The layer of diamond sandwiched within the substrate of the die 160 also removes heat from the silicon layer with the integrated circuitry thereon. As a result, the diamond layer within the die 160 and the heat sink 150 both act to remove heat from the integrated circuitry of the die 160.

The layer of diamond sandwiched between a first layer of silicon and a second layer of silicon is formed at the wafer level. When the wafer is diced or singulated into individual die, following circuit fabrication, the layer of diamond sandwiched between a first layer of silicon and a second layer of silicon is carried into the individual die. It should be noted that the layer of diamond sandwiched between a first layer of silicon and a second layer of silicon is not limited to any particular type of component. Therefore, the structure can be used in any of the components 130, 132, 134, 136, 138 and is not limited to use only in a central processing chip or microprocessor. Generally, however, the microprocessor is a component that generates the most heat and therefore most likely to have a die with the layer of diamond sandwiched between a first layer of silicon and a second layer of silicon to aid in the removal of heat from the circuitry of the component.

As shown in FIG. 1, the printed circuit board 100 includes a first edge connector 140 and a second edge connector 142. As shown in FIG. 1 there are external traces, such as electrical trace 110, on the external surface 120 of the printed circuit board 100 that connect to certain of the outputs associated with the first edge connector 140. Other traces that connect with the edge connectors 140, 142 will have traces internal to the printed circuit board 100.

FIG. 2 is a side view of a heat dissipation device 200 including a diamond layer 210 sandwiched between a first silicon layer 220 and a second silicon layer 230, according to an embodiment of this invention. The first layer of silicon 220 includes a device quality silicon layer 221 and an epitaxial layer 222. An integrated circuit or the electronics associated with an integrated circuit is formed in the epitaxial layer 222. The second layer of silicon 230 includes a layer of polysilicon 231 and a layer of single or polycrystalline silicon 232. The single layer of single or polycrystalline silicon 232 is bonded to the layer of polysilicon 231 at a joint 234. The heat dissipation device 200, shown in FIG. 2, includes electronics or the circuitry that forms the electronics in the epitaxial layer 222. Leads are also placed on the heat dissipation device 200 to form the die 160 shown in FIG. 1. The result is that a diamond layer 210 is buried within the substrate upon which the integrated circuit device is formed. In the alternative, the diamond layer 210 is buried in the substrate on which the device is formed. The diamond layer 210 conducts heat away from the first silicon layer 220 which includes the device quality silicon substrate 221 and the epitaxial layer 222.

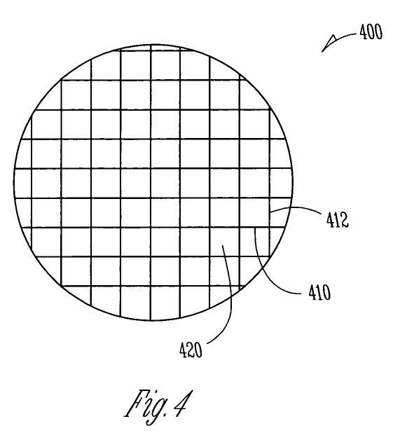

FIG. 3 is a side view of a heat dissipation device 300 that includes a diamond layer 210 sandwiched between a first silicon layer 220 and a second silicon layer 230, according to an embodiment of this invention. The heat dissipation device 300 includes many of the same elements as the heat dissipation device 200. For example, the second layer of silicon 230 includes a layer of polysilicon 231 and a layer of single or polycrystalline silicon 232 which are joined at the joint 234. The difference between heat dissipation device 200 and heat dissipation device 300 is that the first layer of silicon 220 includes a buried oxide layer 321. The first layer includes a device quality silicon layer 221 and an epitaxial layer 222. The buried oxide layer 321 is positioned between the device quality silicon 221 and the epitaxial layer 222. The buried oxide layer 321 is buried in the first layer of silicon 220. Devices or the electronics necessary to form an integrated circuit are formed in the epitaxial layer 222. When the heat dissipation device 300 includes leads in the form of bumps or pins or similar leads as well as the electronics or devices in the epitaxial layer 222, the heat dissipation device 300 corresponds to another embodiment of the die 160 (shown in FIG. 1). The heat dissipation device 300 corresponds to a device that is formed with a silicon on insulator (SOI) layer in which the devices corresponding to the integrated circuit are formed. Again, the diamond layer 210 is sandwiched between a first layer of silicon 220 and a second layer of silicon 230. The diamond layer 210 can also be thought of as being buried within the substrate on which the device or the electronics for the integrated circuit are formed. The diamond layer 210 is positioned close to the device layer or epitaxial layer 222 so that it can remove heat from the device or epitaxial layer and prevent hot spots from forming in the device or epitaxial layer 222.

A heat dissipation device includes a first silicon layer 220, a second silicon layer 230, and a diamond layer 210 sandwiched between the first silicon layer 220 and the second silicon layer 230. The layer of diamond 210 is deposited on one of the first layer of silicon 220 or the second layer of silicon 230. The other of the first layer of silicon 220 and the second layer of silicon 230 is formed on the layer of diamond 210. The diamond layer 210 has a thickness in the range of 50 microns to 200 microns. Electrical circuitry is formed in the epitaxial layer 222 of one of the first silicon layer 220 or the second silicon layer 230. The electrical circuitry is formed on the thinnest of the first layer of silicon 220 and the second layer of silicon 230.

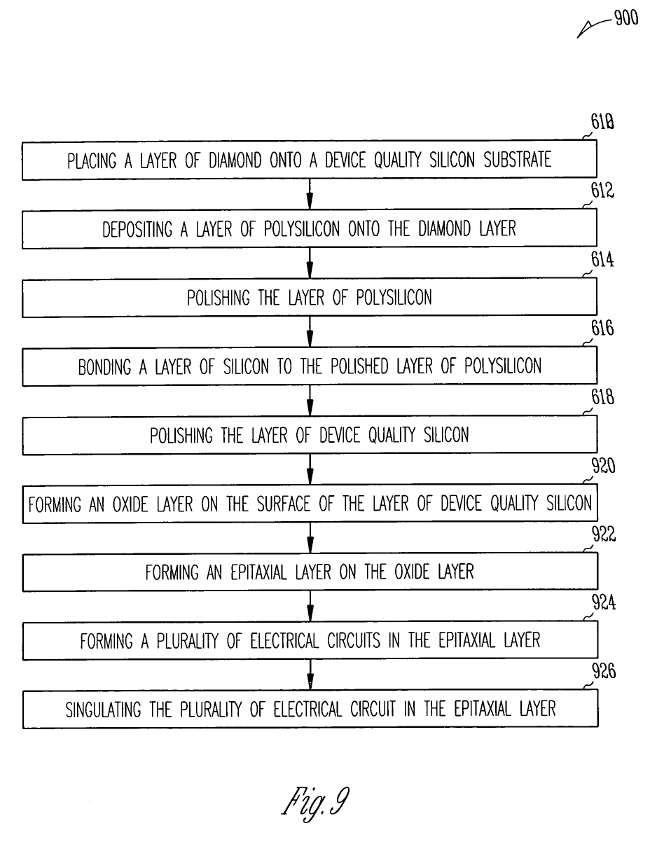

One of the first layer of silicon 220 and the second layer of silicon 230 includes a layer of polysilicon 231 adjacent the layer of diamond 210. The surface of the diamond layer 210 may include at least one irregularity (shown in FIGS. 7A-7B). The layer of polysilicon 231 adjacent the surface of the layer of diamond 210 is sufficiently thick to cover the irregularity in the diamond layer 210. One of the first layer of silicon and the second layer of silicon further includes the epitaxial layer 222 adjacent the single crystal or device quality silicon layer 221. In some embodiments, one of the first layer of silicon 220 and the second layer of silicon 230 further includes a buried oxide layer 321 adjacent the single crystal or device quality silicon layer 221, and an epitaxial layer 222 adjacent the buried oxide layer 321. One of the first layer of silicon 220 and the second layer of silicon 230 further includes a layer of silicon 232 bonded to the layer of polysilicon 231.

In some embodiments, the second layer of silicon 230 includes a layer of polysilicon 231 adjacent the layer of diamond 210, and a layer of silicon 232 attached to the layer of polysilicon 231. The first layer of silicon 220 further includes an epitaxial layer 222 adjacent the single crystal or device quality silicon layer 221, and electrical circuitry formed in the epitaxial layer 222. In another embodiment of the invention, the second layer of silicon 230 includes a layer of polysilicon 231 adjacent the layer of diamond 210, and a layer of silicon 232 attached to the layer of polysilicon 231. The first layer of silicon 220 includes a buried oxide layer 321 adjacent the single crystal or device quality silicon layer 221, and an epitaxial layer 222 adjacent the buried oxide layer 321, and electrical circuitry formed in the epitaxial layer 222.

FIG. 4 is a schematic view of a wafer 400 that includes a buried diamond layer sandwiched between a first silicon layer and a second silicon layer, according to an embodiment of this invention. In order to form a die 160 a wafer 400 is processed to form a plurality of individual dies on the wafer 400. In other words, in order to form a number of individual dies a wafer is treated to form the various layers that are within the die. After treatment of the wafer 400 is complete and the epitaxial layer (shown in FIGS. 2 and 3) has electronics or devices formed therein corresponding to integrated circuits or a microprocessor or the like and leads, such as solder bumps, are provided, the wafer 400 is singulated. Singulation means the wafer 400 is cut along lines such as 410 and 412 to produce an individual die 420. Before singulation, the die 420 is part of the wafer 400. Die 420, as shown in FIG. 4, is surrounded by cut lines such as 410 and 412. Thus, the layers within a die 160 (shown in FIG. 2) or 420 are the same as the layers within the wafer 400, after processing the wafer to form the die or heat dissipation device having a buried diamond layer 210 surrounded by a first layer of silicon 220 and a second layer of silicon 230 (shown in FIG. 2).

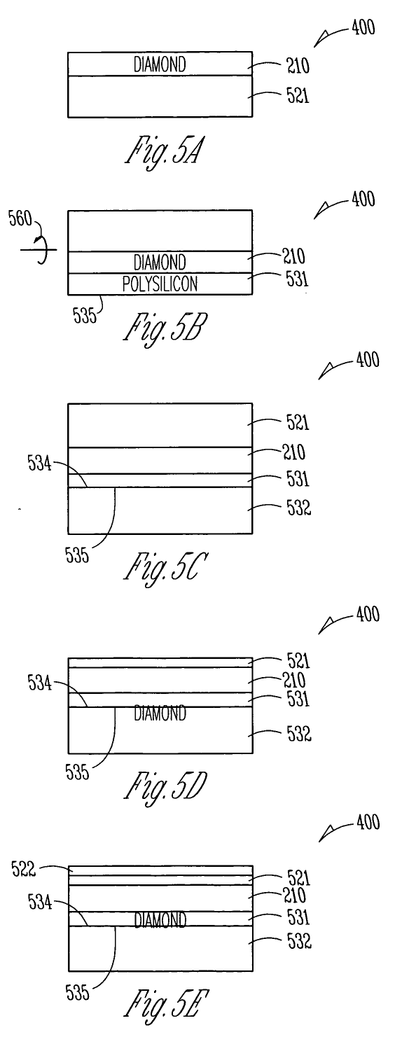

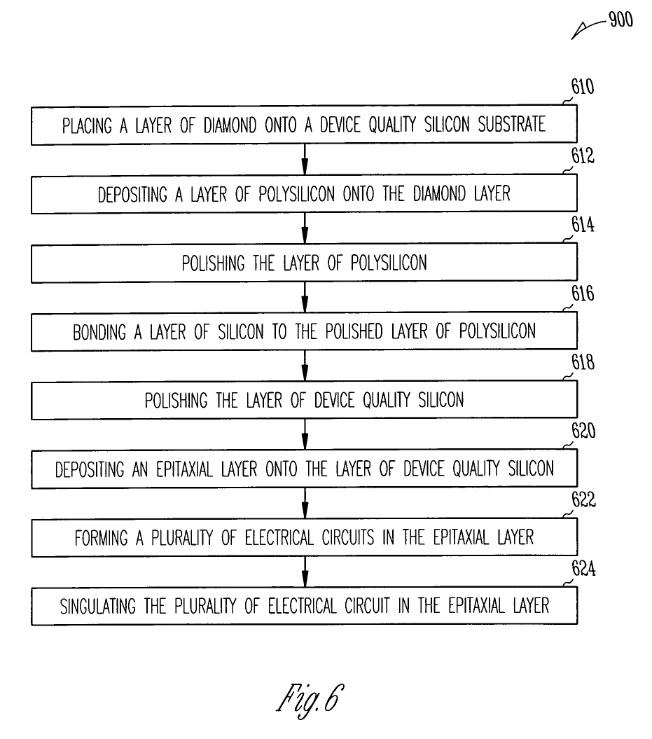

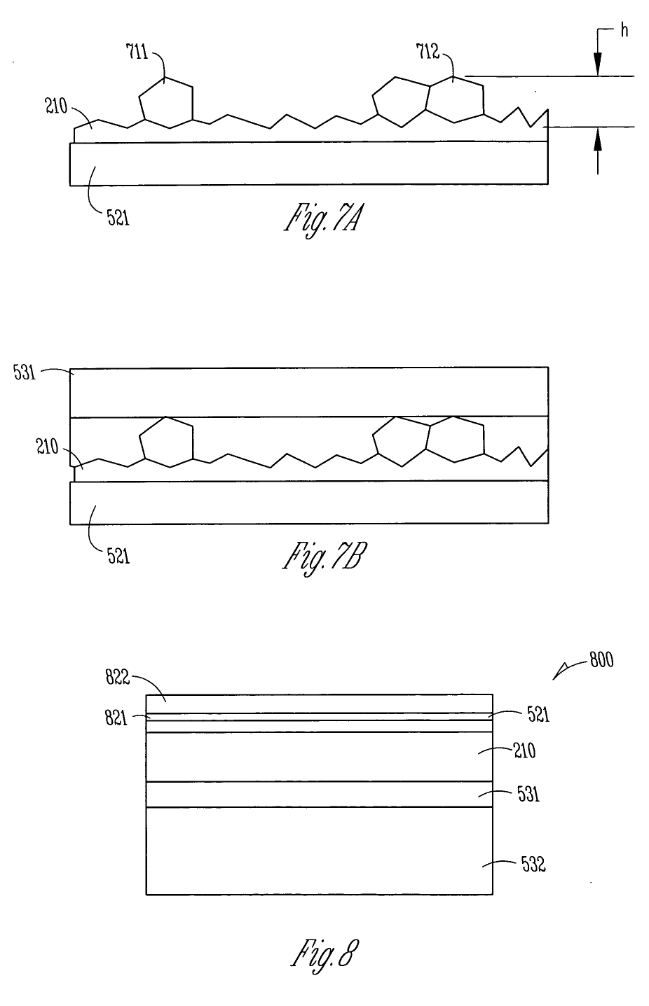

The formation of a die or wafer or heat dissipation device will now be discussed with respect to FIGS. 5A to 5E. FIGS. 5A to 5E show the various stages in the process of forming the die, or wafer 400 that includes the buried diamond layer 210 sandwiched between a first layer of silicon 220 and a second layer of silicon 230. For the sake of clarity, FIGS. 5A to 5E will be discussed as though a portion of a wafer 400 is being shown, since the wafer 400 and the layers within the wafer 400 are formed before the wafer 400 is singulated into individual die 420, 160.

FIG. 5A illustrates a wafer 400 or a heat dissipation device after a layer of diamond 210 has been placed on the wafer during the process of forming the buried diamond layer, according to an embodiment of this invention. The initial starting point is a wafer of device quality or single crystalline silicon 521. The diamond layer 210 is deposited upon the device quality silicon wafer 521 using a plasma enhanced chemical vapor deposition technique (CVD). The diamond layer 210 is actually a film applied with a plasma-enhanced CVD technique. The film has a thickness of approximately 50 to 200 micron. It should be noted that diamond has the highest thermal conductivity of all known materials. For example, diamond has a conductivity which is five times the conductivity of copper. Diamond then, is useful in carrying away heat from a portion of a device, such as the device layer of a die 160, 420. It has been found that an embedded diamond film 210 need not be very thick to optimize performance. For example, it has been found that at approximately 200 microns, the benefits of diamond are maximized. As a result the diamond layer 210 has a thickness in the range of 50-200 microns.

The diamond layer 210 is deposited on a wafer-sized silicon substrate of device quality silicon 521 in a vapor deposition chamber. Within the vapor deposition chamber, the pressure is 20-50 Torr and the temperature of the chamber is in the range of 800-900° C. The process gases included in the chamber are methane and hydrogen. The methane levels typically vary in the range of 0.5-5%. The diamond layer 210 is deposited on the wafer of device quality silicon 521 at a deposition rate of approximately 10-25 microns per hour. As a result, it takes from four to ten hours to deposit a diamond film or diamond layer 210 that is 100 microns thick. It takes from eight to twenty hours to deposit a diamond film or diamond layer 210 that is approximately 200 microns thick. Plasma is activated in the chamber using any of a variety of techniques, including radio-frequency induced glow discharge, DC arc jets, a microwave CVD or other plasma activation source. Plasma activation is used to induce a plasma field in the deposition gas and provides for low temperatures as well as good film uniformity and through put.

The next step is to deposit a polysilicon layer 531 onto the diamond film or diamond layer 210. The polysilicon film 531 is deposited using CVD techniques. The polysilicon is deposited in a chamber that has an environment which is at approximately 600-650° C. The deposition can be from either 100% saline or gas streams containing N₂ or H₂. The polysilicon film or layer 531 formed has a thickness sufficient to completely cover the diamond film or diamond layer 210.

FIG. 5B illustrates wafer 400 or heat dissipation device after a layer of polysilicon 531 has been placed over the layer of diamond 220 during the process of forming the buried diamond layer, according to an embodiment of this invention. In FIG. 5B, the wafer 400 has been flipped over as depicted by arrow 560. The polysilicon film 531 is polished. Specifically a surface 535 of the polysilicon film is polished.

FIG. 5C illustrates a wafer or heat dissipation device after another layer of silicon is attached to the polysilicon layer of the wafer during the process of forming the buried diamond layer, according to an embodiment of this invention. FIG. 5C shows the wafer 400 or heat dissipation device after another layer of silicon 532 is bonded to the polysilicon layer 531 along the surface 535 to form joint 534. The additional layer of silicon 532 need not be a single crystal but can be a low cost polycrystalline wafer manufactured using ingot casting technology. The silicon layer 532 is an inexpensive “handle” that is bonded to the film or layer of polysilicon 531 on the wafer. The “handle” provides stability to the wafer and also eases in the handling of the wafer during the manufacturing process.

FIG. 5D illustrates a wafer or neat dissipation device after the device quality silicon layer has been thinned and polished during the process of forming the buried diamond layer, according to an embodiment of this invention. FIG. 5D illustrates a wafer or heat dissipation device 400 after the device quality or silicon substrate 521 has been thinned to a thickness of approximately 2.75 microns. The device quality silicon substrate layer 521 is thinned using wafer grinding and chemical-mechanical polishing (CMP) processes. By thinning the device quality silicon layer 521 to the thickness of approximately 2.75 microns, the active device layer is produced.

FIG. 5E illustrates a wafer or heat dissipation device after an epitaxial layer has been placed on the device quality layer during the process of forming the buried diamond layer, according to an embodiment of this invention. The next step in the process is to place or deposit an epitaxial film 522 on the thinned device quality silicon layer 521. Devices or electronics are formed in the epitaxial film 522 and, therefore, the devices are very closely spaced with respect to the buried diamond layer 210 within the wafer 400. This, of course, aids in removing heat from the devices formed in the epitaxial film 522 and also prevents hot spots from forming when the devices are in use. It should be noted that the wafer 400 shown in FIG. 5E has the same layer structure as the heat dissipation device 200 shown in FIG. 2. The reference numbers are changed merely to reflect that particularly heat dissipation device 400 shown in FIG. 5E is a wafer 400.

FIG. 6 is a flow diagram showing a method 600 for forming a buried diamond layer 210 on a wafer 400, according to an embodiment of the invention shown in FIGS. 5A to 5E. The method for forming an electronic device 600 includes placing a layer of diamond onto a device quality silicon substrate 610, and depositing a layer of polysilicon 531 onto the diamond layer 612. The layer of diamond 210 includes at least one surface irregularity (shown in FIGS. 7A-7B). Depositing a layer of polysilicon 531 onto the diamond layer 210 includes depositing a layer of polysilicon 531 sufficiently thick to cover the surface irregularity. The method 600 further includes polishing the layer of polysilicon 614. The method 600 further includes bonding a layer of silicon to the polished layer of polysilicon 616. The method 600 further includes polishing the layer of device quality silicon 618. In some embodiments, the layer of device quality silicon is polished to a thickness in the range of 1 to 20 microns. In some embodiments, the method for forming an electronic device further includes polishing the layer of device quality silicon to a thickness in the range of 2 to 10 microns. An epitaxial layer is deposited onto the layer of device quality silicon 620. The method for forming an electronic device 600 further includes forming a plurality of electrical circuits in the epitaxial layer 622, and singulating the plurality of electrical circuit in the epitaxial layer 624.

FIGS. 7A and 7B provide a close-up view of the step of depositing a layer of polysilicon onto the diamond layer 612. FIG. 7A illustrates the wafer or heat dissipation device before a layer of polysilicon is placed over the layer of diamond during the process of forming the buried diamond layer, according to an embodiment of this invention. FIG. 7A shows the device quality substrate 521 having a layer of diamond 210 deposited thereon. FIG. 7A shows that surface irregularities 711 and 712 form as a result of depositing the diamond film or diamond layer 210 onto the device quality silicon substrate 521. The surface irregularities are large local diamond crystals resulting from spurious nucleation at possible contamination sites on the wafer. The large surface irregularities 711 and 712 are sometimes referred to as diamond spikes. As shown in FIG. 7A, the diamond film has a thickness h that has a range from 50 to 200 microns or micrometers.

FIG. 7B illustrates the wafer or heat dissipation device after a layer of polysilicon 531 is placed over the layer of diamond 210 during the process of forming the buried diamond layer, according to an embodiment of the invention. As mentioned previously, the diamond spikes or surface irregularities 711 and 712 may form as a result of depositing the diamond film or diamond layer 210 onto the device quality silicon substrate 521. The polysilicon film or polysilicon layer 531 is deposited onto the diamond layer 210 until the surface irregularities, such as diamond spikes 711 and 712, are fully covered. The advantage of this process is that the diamond spikes 711, 712 or surface irregularities need not be removed before further processing (beyond step 610 in FIG. 6) occurs. The polysilicon layer covers the diamond spikes and presents a flat surface to which the silicon handle or layer 232 in FIGS. 2 and 3, or layer 532 in FIGS. 5C to 5E, can be bonded or attached. A polysilicon layer 531 of approximately 50 or more microns in thickness over the diamond layer 210 can also compensate for any coefficient of thermal expansion mismatch stresses between the diamond layer 210 and the silicon wafer 400 on which the diamond layer 210 was deposited. Therefore, the polysilicon layer 531 also lessens the effect of wafer bow and warp.

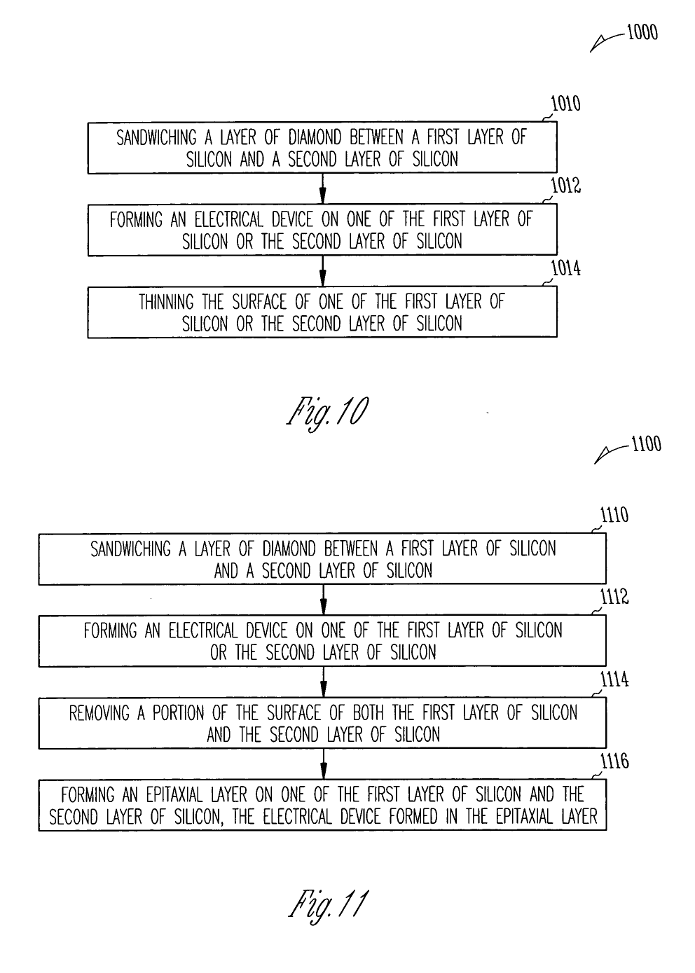

FIG. 8 illustrates a wafer or heat dissipation device 800 after a buried oxide layer 821 has been placed on the device quality silicon layer 521 and after an epitaxial layer 822 has been placed on the buried oxide layer 821 during the process of forming the buried diamond layer, according to an embodiment of this invention. FIG. 8 shows a wafer 800 which has been processed to provide a silicon-on-insulator (SOI) structure. The wafer 800 is treated the same as the wafer 400 or processed the same as the wafer 400 through the step 618 in the method for forming an electronic device 600 shown in FIG. 6. Thus, the wafer 400 and the wafer 800 appear identical in terms of processing in FIGS. 5A to 5D. The wafer 800 includes the device quality silicon layer 521, a diamond layer 210, a polysilicon layer 531 and a silicon handle 532. FIG. 8, then would be substituted for FIG. 5E when shown after the various process steps. The SOI structure is fabricated by bonding a thin-oxidized silicon film 821 to the thin, device quality silicon layer 521. The oxidized silicon film can be added to the device quality silicon layer 521 using a layer transfer process or any other similar process. An epitaxial layer 822 is then formed on the thin, oxidized silicon film 821. Devices are then formed in the epitaxial layer 822. It should be noted that this structure shown in FIG. 8 is also completely compatible with any strained silicon concepts, such as combining the structure with SiGe films.

FIG. 9 is a flow diagram showing a method for forming a buried diamond layer on a wafer 900 according to an embodiment of this invention. The method for forming an electronic device 900 includes placing a layer of diamond onto a device quality silicon substrate 610 and depositing a layer of polysilicon 531 onto the diamond layer 612. The layer of diamond 210 includes at least one surface irregularity (shown in FIGS. 7A-7B). Depositing a layer of polysilicon 531 onto the diamond layer 210 includes depositing a layer of polysilicon 531 sufficiently thick to cover the surface irregularity. The method 900 further includes polishing the layer of polysilicon 614. The method 900 further includes bonding a layer of silicon to the polished layer of polysilicon 616. The method 900 further includes polishing the layer of device quality silicon 618. In some embodiments, the layer of device quality silicon is polished to a thickness in the range of 1 to 20 microns. In some embodiments, the method for forming an electronic device further includes polishing the layer of device quality silicon to a thickness in the range of 2 to 10 microns. An oxide layer is formed on the surface of the layer of device quality silicon 922, and a bonded device layer is formed on the oxide layer 922. The method for forming an electronic device 900 further includes forming a plurality of electrical circuits in the bonded device layer 924 and singulating the plurality of electrical circuit in the epitaxial layer 926.

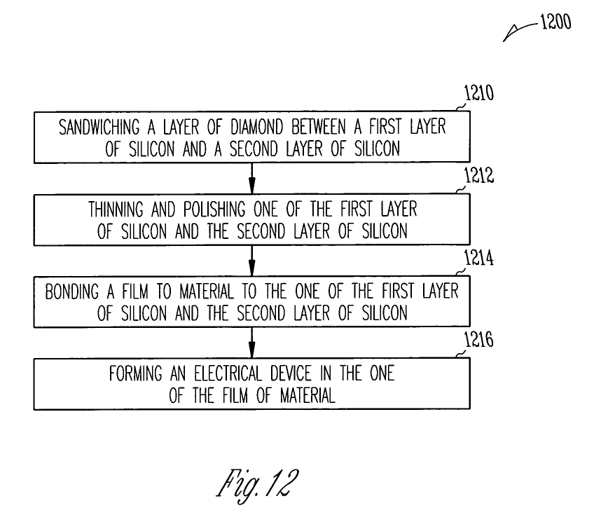

FIG. 10 is a flow diagram of a method for forming a buried diamond layer on a wafer 1000, according to yet another embodiment of this invention. The method for forming an electronic device 1000 includes sandwiching a layer of diamond between a first layer of silicon and a second layer of silicon 1010, and forming an electrical device on one of the first layer of silicon or the second layer of silicon 1012. The method also includes thinning the surface of one of the first layer of silicon or the second layer of silicon 1014.

FIG. 11 is a flow diagram of a method for forming a buried diamond layer on a wafer 1100, according to still another embodiment of this invention. The method for forming the electronic device 1100 includes sandwiching a layer of diamond between a first layer of silicon and a second layer of silicon 1110 and forming an electrical device on one of the first layers of silicon or the second layer of silicon 1112. A portion of the surface of both the first layer of silicon and the second layer of silicon are removed 1114. One of the first layer and the second layer is thinned before fabricating an electrical device therein. The layer is thinned so that the electrical device is in closer proximity to the diamond layer. A portion of the other of the first layer and second layer is removed so that a silicon handle can be bonded to the smoothed surface. The method 1100 further includes forming an epitaxial layer on one of the first layer of silicon and the second layer of silicon 1116. The electrical device formed in the epitaxial layer.

FIG. 12 is a flow diagram of a method for forming an electronic device 1200, according to an embodiment of this invention. The method 1200 includes sandwiching a layer of diamond between a first layer of silicon and a second layer of silicon 1210, and thinning and polishing one of the first layer of silicon and the second layer of silicon 1212. The method also includes bonding a film to material to the one of the first layer of silicon and the second layer of silicon 1214, and forming an electrical device in the one of the film of material 1216. In one embodiment of the method 1200, the film of material is a thin film of Germanium, and in another embodiment the film of material is a thin film of strained silicon.

The foregoing description of the specific embodiments reveals the general nature of the invention sufficiently that others can, by applying current knowledge, readily modify and/or adapt it for various applications without departing from the generic concept, and therefore such adaptations and modifications are intended to be comprehended within the meaning and range of equivalents of the disclosed embodiments.

It is to be understood that the phraseology or terminology employed herein is for the purpose of description and not of limitation. Accordingly, the invention is intended to embrace all such alternatives, modifications, equivalents and variations as fall within the spirit and broad scope of the appended claims.

1. A heat dissipation device comprising:
a first silicon layer;
a second silicon layer; and
a diamond layer sandwiched between the first silicon layer and the second silicon layer.

2. The heat dissipation device of claim 1 wherein the layer of diamond is deposited on one of the first layer of silicon or the second layer of silicon.

3. The heat dissipation device of claim 2 wherein the other of the first layer of silicon and the second layer of silicon is formed on the layer of diamond.

4. The heat dissipation device of claim 1 wherein the diamond layer has a thickness in the range of 50 microns to 200 microns.

5. The heat dissipation device of claim 1 further comprising electrical circuitry formed in one of the first silicon layer or the second silicon layer.

6. The heat dissipation device of claim 5 wherein the electrical circuitry is formed on the thinnest of the first layer of silicon and the second layer of silicon.

7. The heat dissipation device of claim 1 wherein one of the first layer of silicon and the second layer of silicon includes a layer of polysilicon adjacent the layer of diamond.

8. The heat dissipation device of claim 7 wherein a surface of the diamond layer includes at least one irregularity, the layer of polysilicon adjacent the surface of the layer of diamond being sufficiently thick to cover the irregularity in the diamond layer.

9. The heat dissipation device of claim 7 wherein the one of the first layer of silicon and the second layer of silicon further includes a layer of silicon bonded to the layer of polysilicon.

10. The heat dissipation device of claim 1 wherein one of the first layer of silicon and the second layer of silicon further includes an epitaxial layer adjacent the single crystal silicon layer.

11. The heat dissipation device of claim 1 wherein one of the first layer of silicon and the second layer of silicon further includes:
a buried oxide layer adjacent the single crystal silicon layer; and
an epitaxial layer adjacent the buried oxide layer.

12. The heat dissipation device of claim 1 wherein the first layer further comprises:
a layer of polysilicon adjacent the layer of diamond; and
a layer of silicon attached to the layer of polysilicon;
and wherein the second layer further comprises:
an epitaxial layer adjacent the single crystal silicon layer; and
electrical circuitry formed in the epitaxial layer.

13. The heat dissipation device of claim 1 wherein the first layer further comprises:
a layer of polysilicon adjacent the layer of diamond; and
a layer of silicon attached to the layer of polysilicon;
and wherein the second layer further comprises:
a buried oxide layer adjacent the single crystal silicon layer;
an epitaxial layer adjacent the buried oxide layer; and
electrical circuitry formed in the epitaxial layer.

14. A method for forming an electronic device comprising:
placing a layer of diamond onto a device quality silicon substrate; and
depositing a layer of polysilicon onto the diamond layer.

15. The method for forming an electronic device of claim 14 wherein the layer of diamond includes at least one surface irregularity and wherein depositing a layer of polysilicon onto the diamond layer includes depositing a layer of polysilicon sufficiently thick to cover the surface irregularity.

16. The method for forming an electronic device of claim 14 further comprising polishing the layer of polysilicon.

17. The method for forming an electronic device of claim 16 further comprising bonding a layer of silicon to the polished layer of polysilicon.

18. The method for forming an electronic device of claim 14 further comprising polishing the layer of device quality silicon.

19. The method for forming an electronic device of claim 14 further comprising polishing the layer of device quality silicon to a thickness in the range of 1 to 20 microns.

20. The method for forming an electronic device of claim 14 further comprising polishing the layer of device quality silicon to a thickness in the range of 2 to 10 microns.

21. The method for forming an electronic device of claim 18 further comprising depositing an epitaxial layer onto the layer of device quality silicon.

22. The method for forming an electronic device of claim 18 further comprising:
forming an oxide layer on the surface of the layer of device quality silicon; and
forming an epitaxial layer on the oxide layer.

23. The method for forming an electronic device of claim 22 further comprising forming a plurality of electrical circuits in the epitaxial layer.

24. The method for forming an electronic device of claim 23 further comprising singulating the plurality of electrical circuit in the epitaxial layer.

25. The method for forming an electronic device of claim 18 further comprising forming an epitaxial layer on the surface of the layer of device quality silicon.

26. The method for forming an electronic device of claim 25 further comprising forming a plurality of electrical circuits in the epitaxial layer.

27. The method for forming an electronic device of claim 26 further comprising singulating the plurality of electrical circuit in the epitaxial layer.

28. A method for forming an electronic device comprising:
sandwiching a layer of diamond between a first layer of silicon and a second layer of silicon; and
forming an electrical device on one of the first layer of silicon or the second layer of silicon.

29. The method of claim 28 further comprising thinning the surface of one of the first layer of silicon or the second layer of silicon.

30. The method of claim 28 further comprising polishing the surface of both the first layer of silicon and the second layer of silicon.

31. The method of claim 28 further comprising:
polishing the surface of both the first layer of silicon and the second layer of silicon;
forming an epitaxial layer on one of the first layer of silicon and the second layer of silicon, the electrical device formed in the epitaxial layer.

32. A method for forming an electronic device comprising:
sandwiching a layer of diamond between a first layer of silicon and a second layer of silicon; and
thinning and polishing one of the first layer of silicon and the second layer of silicon;
bonding a film to material to the one of the first layer of silicon and the second layer of silicon; and
forming an electrical device in the one of the film of material.

33. The method of claim 32 wherein the film of material is a thin film of Germanium.

34. The method of claim 32 wherein the film of material is a thin film of strained silicon.
